(19) United States
(12) Patent Application Publication
(10) Pub. No.: US 2026/0362686 A1
(43) Pub. Date: Nov. 12, 2026

(54) 3D HIGH-DENSITY, MULTI-VALUED MEMORY STACK

(71) Applicant: Taalas Inc., Toronto (CA)

(72) Inventors: Ljubisa Bajic, Toronto (CA); Dragoljub Ignjatovic, North York (CA); Lejla Bajic, North York (CA)

(21) Appl. No.: 19/674,667

(22) Filed: May 12, 2026

(30) Foreign Application Priority Data
May 12, 2025 (WO) PCT/CA2025/050689

(51) Int. Cl. H10B 20/00; G11C 17/18; H10D 8/00; H10D 8/01; H10D 8/60; H10D 8/70; H10W 20/41; H10W 20/42; H10W 20/43; H10W 20/40

(52) U.S. Cl. CPC H10B 20/27; G11C 17/18; H10D 8/045; H10D 8/051; H10D 8/053; H10D 8/411; H10D 8/60; H10D 8/70; H10W 20/42; H10W 20/43; H10W 20/435; H10W 20/498

(57) ABSTRACT

Methods and systems related to high-density, multi-valued read only memory are disclosed herein. A multi-layer read-only memory array includes vertically stacked memory layers. Each memory layer includes bit lines positioned on a first set of metal layers and value lines positioned on a second set of metal layers. The value lines and bit lines are selectively connected by rectifying contacts configured to allow one-way current flow.

### CROSS-REFERENCE TO RELATED APPLICATION

This application claims the benefit of and priority to the Patent Cooperation Treaty (PCT) Application No. PCT/CA2025/050689 filed with Canadian Intellectual Property Office on May 12, 2025, and titled “3D HIGH-DENSITY, MULTI-VALUED MEMORY STACK,” the entire content of which is incorporated herein by reference in its entirety.

### TECHNICAL FIELD

This disclosure relates to computational architectures, in particular, to a high-density, multi-valued read only memory (ROM) array architecture that enables vertical stacking and supports in-memory processing.

### BACKGROUND

In recent years, computing architectures for applications like artificial intelligence (AI), machine learning (ML), and cryptography have advanced significantly in processing efficiency, but memory technologies have not kept pace. This imbalance has led to memory, particularly dynamic random-access memory (DRAM) and static random-access memory (SRAM), accounting for a disproportionate share of system costs.

The performance gap between memory and compute components is also expected to widen further as data structures grow. Current SRAM and DRAM technologies face significant technical limitations when applied to AI and ML workloads, for example, in terms of density, scalability, and energy efficiency. SRAM consumes a large silicon area per bit due to its multi-transistor design, making it impractical for storing the large parameter sets needed in modern neural networks. DRAM offers higher density than SRAM but suffers from high latency, refresh overhead, and poor integration with logic circuits, requiring constant data movement between memory and processors. These constraints result in high energy costs and limited throughput for AI applications.

Hence, an approach for designing advanced memory systems may be desirable in improving storage density, compute locality, and energy efficiency to better support computing architectures that increasingly optimize complex computations.

### SUMMARY

To address the aforementioned shortcomings, methods and computing architectures related to a high-density, multi-valued ROM array that enables vertical stacking and supports in-memory processing are disclosed herein. In some embodiments, a multi-layer read-only memory array comprises a plurality of vertically stacked memory layers, each memory layer comprising a plurality of bit lines positioned on a first set of metal layers and a plurality of value lines positioned on a second set of metal layers. The plurality of value lines and the plurality of bit lines are selectively connected by rectifying contacts configured to allow one-way current flow.

In some embodiments, the memory array allows metal-pitch density by removing transistors from and including only the metal layers in associated storage regions. In some embodiments, the rectifying contacts comprise Schottky barrier vias, PN junction vias, or two-dimensional based tunneling vias. In some embodiments, the memory array is mask-programmable. In some embodiments, each memory cell of the memory array stores a multi-bit value corresponding to a number of the value lines, where the multi-bit value is read by sequentially performing single-value, single-bit (SVSB) sense operations across the associated value lines. In some embodiments, values stored in the memory array represent neural network parameters, and the values are used to perform vector-by-matrix multiplications. In some embodiments, memory density is improved by eliminating word line and access transistor routing, and in-memory compute logic is located outside the storage fabric of the memory array.

In some embodiments, a method of manufacturing a three-dimensional (3D) read-only memory array is disclosed herein. The method comprises etching a pair of contact holes at a specific position of a first metal layer and a second metal layer, forming rectifying vias through each pair of contact holes by depositing one or more doped semiconductor layers or metal-semiconductor junctions, and selectively connecting value lines to bit lines based on placement of the rectifying vias. In some embodiments, the method further comprises repeating the etching, forming rectifying vias, and selectively connecting steps on additional metal layers to create the 3D memory array.

In some embodiments, the rectifying vias are selectively formed between the value lines and bit lines such that activation of one of the value lines causes only the bit lines connected through the rectifying vias to transition to an active state during operation of the 3D memory array. In some embodiments, the 3D memory array comprises a plurality of metal layers stacked vertically. In some embodiments, the rectifying contacts comprise Schottky barrier vias, PN junction vias, or two-dimensional based tunneling vias.

In some embodiments, a method for reading data from a memory array comprising a plurality of bit lines and a plurality of value lines is disclosed herein. The method comprises pre-charging the plurality of bit lines to an inactive state sensing and driving a specific value line of the plurality of value lines while setting remaining value lines to an inactive state, detecting one or more bit lines of the plurality of bit lines transitioned to an active state, where the one or more bit lines are electrically coupled to the sensed value line by one or more rectifying diode vias, and outputting a value as a result for reading the memory array based on the detecting the one or more bit lines transitioned to the active state.

In some embodiments, active states of the one or more bit lines represent stored bits coupled to the sensed value line. In some embodiments, single-value and single-bit (SVSB) sense operations are performed serially across value lines in a given memory row. The method further comprises repeating the SVSB sense operations in succession to read multiple bits from each memory cell of the memory array. In some embodiments, the memory array comprises a plurality of vertically-stacked memory layers. In some embodiments, sensing and driving the specific value line is performed in parallel across the memory layers of the memory array. In some embodiments, values stored in the memory array represent neural network parameters, and the values are used to perform vector-by-matrix multiplications. In some embodiments, the memory array is mask-programmable.

The above and other preferred features, including various novel details of implementation and combination of elements, will now be more particularly described with reference to the accompanying drawings and pointed out in the claims. It will be understood that the particular methods and apparatuses are shown by way of illustration only and not as limitations. As will be understood by those skilled in the art, the principles and features explained herein may be employed in various and numerous embodiments.

### BRIEF DESCRIPTION OF THE DRAWINGS

The disclosed embodiments have advantages and features which will be more readily apparent from the detailed description, the appended claims, and the accompanying figures(or drawings). A brief introduction of the figures is below.

FIG. 1 illustrates a top-down view of an exemplary two-layer 3D memory array constructed using stacked metal layers, according to some embodiments.

FIG. 2 illustrates a side view of the metal stack architecture used in the memory array of FIG. 1, according to some embodiments.

FIG. 3 illustrates a top-down view of an exemplary two-layer 3D memory array with shared bit lines, according to some embodiments.

FIG. 4 illustrates a side view of the metal stack architecture used in the memory array of FIG. 3, according to some embodiments.

FIG. 5 illustrates a flow diagram for a read operation of a memory array, according to some embodiments.

### DETAILED DESCRIPTION

The Figures(FIGS.) and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Reference will now be made in detail to several embodiments, examples of which are illustrated in the accompanying figures. It is noted that wherever practicable similar or like reference numbers may be used in the figures and may indicate similar or like functionality. The figures depict embodiments of the disclosed system (or method) for purposes of illustration only. One skilled in the art will readily recognize from the following description that alternative embodiments of the structures and methods illustrated herein may be employed without departing from the principles disclosed herein.

### Overview

Disclosed herein is a multi-valued read-only memory (ROM) array designed to support vertical stacking and in-memory processing, enabling a highly compact architecture that integrates storage and computation within an exceptionally dense fabric. This multi-valued ROM array offers significant technical advantages in AI, ML, or other applications that require dense storage and high-throughput computation. By vertically stacking multiple memory layers, the system disclosed herein achieves far greater storage density per unit area than traditional planar memory, and thus can be used to hold the large sets of neural network parameters required for inference and training. Moreover, because each memory layer can independently store and access multi-bit data, this architecture supports highly parallelized memory access patterns, enabling efficient execution of matrix-vector operations used in neural networks.

In some embodiments, the high storage density disclosed herein is achieved through two key features (1) memory cells constructed at metal-pitch density without using transistors and (2) a three-dimensional (3D) stacking architecture that allows multiple memory layers to be vertically integrated, constrained only by the available metal and diode via layers in the fabrication process.

The absence of transistors in a memory array may eliminate the area and power overhead associated with conventional SRAM or DRAM cells. In the present system, storage may be implemented using diode-based rectifying contacts, allowing for ultra-compact, metal-pitch memory cells. This not only improves manufacturing scalability and thermal characteristics, but also enables in-memory computation, where operations such as multiplication can be performed directly within the memory array.

The memory storage stack disclosed herein is programmed by inserting rectifying contacts such as Schottky diode, PN-junction diode, etc., between selected value lines and bit lines. These diode vias ensure one-way connections, preventing current from unintentionally propagating through unselected lines and maintaining isolation between memory cells. This rectification is important because, when ordinary metal vias were used, activating one value line would back-drive current into others, causing unwanted signal propagation throughout the memory cells.

### Storage Array Structure

A 3D memory array disclosed herein may include multiple rows of storage. Each row can implement its own private set of value lines, meaning each row is independently addressed and can output a fixed set of values when selected.

The present system allows for multiple value lines, even within one row, to be connected to a given bit line. A bit line is a vertical conductor or wire in a memory array that connects to multiple memory cells within the same column, which enables data (e.g., bits) to be read from or written to a specific memory cell. For example, in a read operation, a bit line may sense and transmit a charge or voltage from an accessed memory cell. A value line is a horizontal conductor in the memory array that connects to multiple memory cells in the same row, which selects which memory cells (e.g., row of memory cells) are accessed for a read or write operation. For example, a value line may be energized (e.g., set to high voltage) to activate all memory cells in a corresponding row to enable the data stored in these cells to be read out. In some embodiments, the value lines and bit lines are connected through rectifying contacts that allow only one-way current flows.

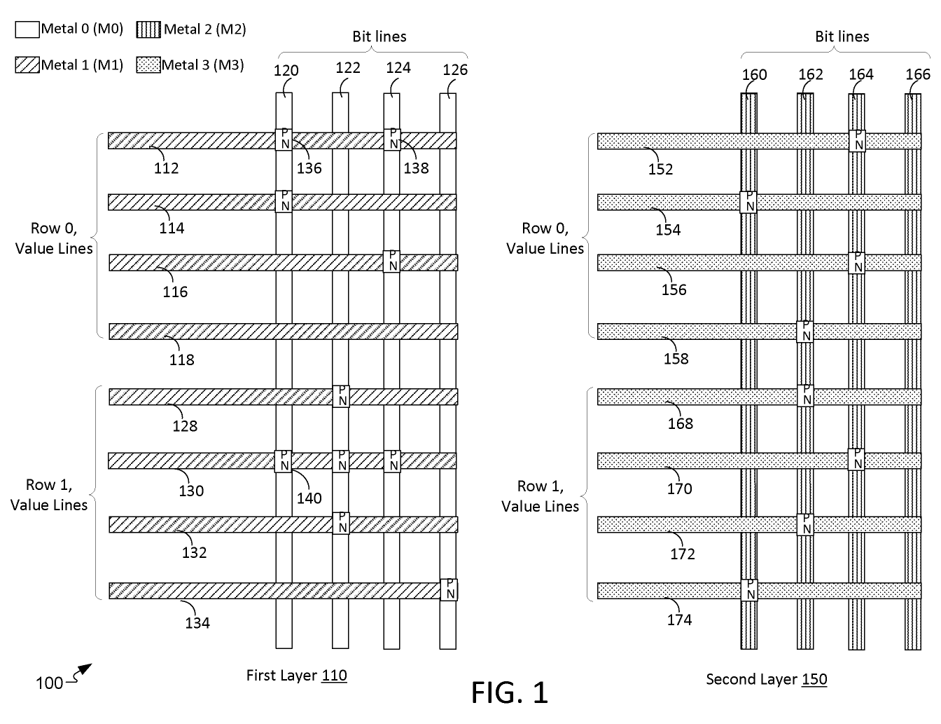

FIG. 1 illustrates a top-down view of an exemplary two-layer 3D memory array 100 constructed using stacked metal layers. As depicted, the 3D memory array 100 includes a first memory layer 110 and a second memory layer 150. Each layer is constructed by placing horizontal value lines and vertical bit lines on separate metal layers. For example, first memory layer 110 includes the stacking of metal layers M0 and M1. Two rows of horizontal value lines are placed in metal 1 (M1), while vertical bit lines are routed in metal 0 (M0). Here, row 0 of M1 includes value lines 112, 114, 116, and 118, and row 1 includes value lines 128, 130, 132, and 134. The corresponding bit lines 120, 122, 124, and 126 are routed in M0.

Similarly, second memory layer 150 is constructed using metal layers M2 and M3. Two additional rows of horizontal value lines are placed in metal 3 (M3), where row 0 includes value lines 152, 154, 156, and 158, and row 1 includes value lines 168, 170, 172, and 174. A set of bit lines is placed in the metal 0 layer. The vertical bit lines for the second memory layer 150, including 160, 162, 164, and 166, may be routed in metal 2 (M2).

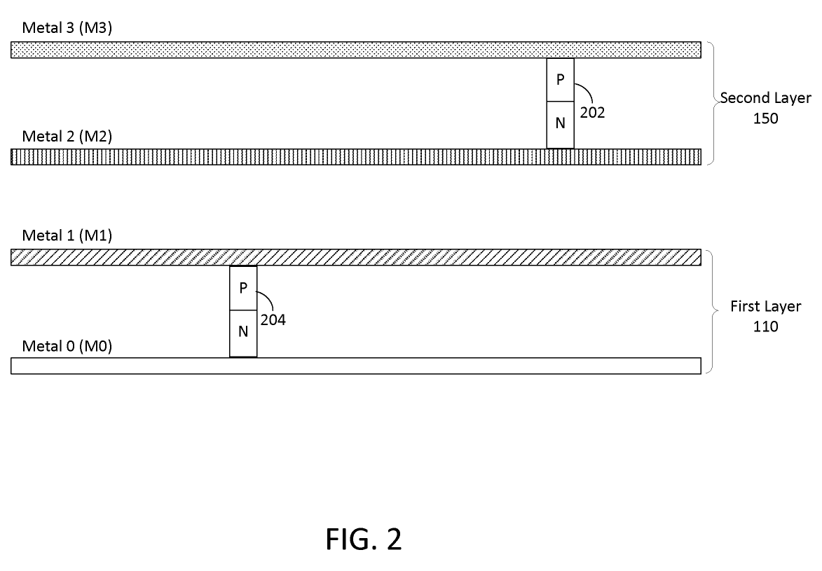

In this example, value lines and bit lines within each memory layer (e.g., 110 or 150) of memory array 100 are selectively connected through rectifying contacts such as PN-junction diodes, implemented between adjacent metal layers. For example, in the first layer 110, value line 112 in row 0 is coupled to bit lines 120 and 124 through PN junction diodes 136 and 138 formed between M0 and M1. These diodes enforce unidirectional current flow, preventing unintended activation of neighboring value lines and enabling clean addressing, as further detailed in FIG. 2.

While FIG. 1 omits peripheral circuitry such as value line drivers, bit line pre-charge transistors, and sense amplifiers for clarity, these elements are assumed to be present in any practical implementation. The structure shown in FIG. 1 is an illustrative example, and other architectural configurations may be used to organize 3D storage arrays based on application-specific layout constraints or fabrication capabilities.

FIG. 2 illustrates a side view of the metal stack architecture used in the memory array 100 of FIG. 1. As shown, the second memory layer 150 is vertically stacked above the first memory layer 110, forming a 3D memory array. Each memory layer 110 or 150 of memory array 100 is constructed using metal interconnect layers, with one-way electrical connections between value lines and bit lines implemented through rectifying contacts such as PN-junctions 202 and 204.

The formation of a PN junction diode via (e.g., 204) between two metal layers (e.g., M0 and M1) may be accomplished through a layered semiconductor process. This is a simplified example for easy understanding, and the formation process will be further detailed below. The process starts by etching the lower metal layer M0. A conformal silicon dioxide (SiO₂) layer is then deposited using chemical vapor deposition (CVD), followed by the etching of a contact hole (analogous to the standard via formation). Next, an N-doped silicon layer is deposited via CVD, and chemical-mechanical polishing (CMP) is used to planarize the surface, leaving doped silicon only within the contact hole. A second SiO₂ layer is deposited, and a second contact hole is etched directly above the first. P-doped silicon is deposited by CVD and again planarized with CMP, leaving P⁺ material only in the upper portion of the via. The structure is then annealed to activate the dopants and form a vertical P-N junction within the via. Processes for building rectifying diodes including PN junctions are further detailed below in the “rectifying diode” section.

In some embodiments, the memory array disclosed herein (e.g., memory array 100) is mask programmable. This means that the memory array can be configured or programmed by changing one or more masks during semiconductor fabrication. A mask is a template used in photolithography to define patterns on the silicon wafer, such as creating connections between layers of material (e.g., metal layers, active regions, etc.).

In some embodiments, the memory array disclosed herein may be programmable using a mask change (e.g., during manufacturing). Vias are small vertical connections that link different layers of materials in a semiconductor device and active regions of semiconductor material. In the present disclosure, masks may be used to define a set of vias (e.g., PN junctions 202 and 204) that electrically connect a set of bit lines in one metal layer to a set of value lines in another metal layer, thereby forming the memory cells. The selection of diode contacts/vias between specific value lines and specific bit lines during chip fabrication encodes the desired data pattern directly into the memory fabric.

In some embodiments, the 3D memory array disclosed herein is strictly mask-programmable. The programming (i.e., the pattern of diode connections) can only be determined during the mask design phase for semiconductor manufacturing. Once manufactured, the pattern is permanent without post-fabrication rewriting.

A notable aspect of the rectifying contacts or diode vias described herein is that these vias allow current to flow only in one direction, which is crucial for maintaining cell isolation. Without these rectifying elements, bidirectional current flow through standard metal vias would cause activation of unintended paths in the grid, resulting in signal leakage and corrupted addressing. The present rectifying diode-based approach ensures that when a value line is activated, only the intended bit lines transition, preserving the integrity of the memory operation.

Because no transistors are used in the construction of the described array, and the diode-isolated structure supports clean, selective addressing, it can be vertically stacked using additional metal layers. While the 3D memory array 100, as illustrated in FIGS. 1 and 2, includes two memory layers and each memory layer uses two metal layers (one for horizontal value lines and one for vertical bit lines), multiple memory layers and/or multiple metal layers can be stacked. As complementary metal-oxide-semiconductor (CMOS) processes support increasing numbers of metal layers, additional memory layers can be stacked above layers 110 and 150 without increasing the planar area, making this architecture highly scalable.

Another key advantage of the memory structure disclosed herein is that no transistors are embedded within the memory storage fabric. Instead, all transistor-based circuitry used for control, sensing, or computation, such as value line drivers, sense amplifiers, and pre-charge units, are physically located beneath the memory array, within the silicon substrate. Because the storage array is built entirely in the metal layers, this configuration allows the silicon area traditionally used for embedded memory to be repurposed for control and compute logic, enabling much higher efficiency. This transistor-free memory plane supports extremely dense vertical stacking of both memory and compute layers.

The memory, designed using the approaches disclosed herein, can have densities limited only by the metal pitch density of the process in which the memory is formed. Metal pitch is a distance between adjacent metal lines in a semiconductor process. It is a key factor in determining how small and dense the wiring can be in an integrated circuit. When the density of a ROM is limited only by this metal pitch, the memory design may maximally utilize the available wiring space within the process constraints, which offers significant benefits for data-intensive applications.

Overall, the design of memory array 100 supports high-density, multi-bit storage, and in-memory computation in a scalable, CMOS-compatible framework. By fully separating the logic circuitry (transistor-based) from the memory fabric (constructed entirely from metal layers), the present architecture enables true three-dimensional integration of computing and storage. This makes the memory design particularly well-suited for AI and ML applications, which demand compact, efficient handling of large parameter sets and intensive computational workloads.

### Stacking Scheme

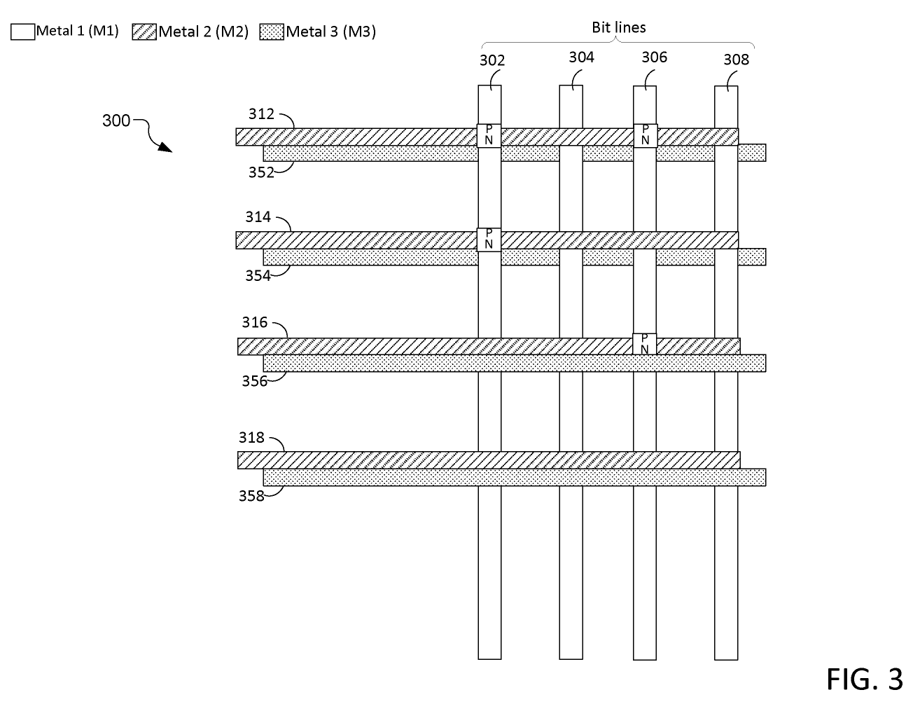

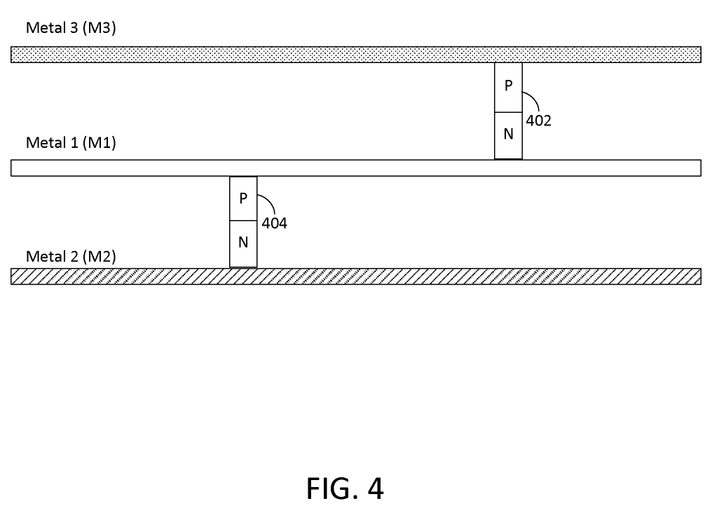

In some embodiments, the present system supports two stacking schemes. As shown in FIGS. 1 and 2, memory array 100 implements a standard stacking configuration, in which each memory layer includes its own dedicated set of bit lines and value lines. In contrast, memory array 300, as described below in FIGS. 3 and 4, utilizes a denser packing approach, where a single set of bit lines is shared across multiple layers of value lines positioned on adjacent metal layers. This shared-bit-line configuration reduces the number of metal layers required per memory layer, thereby increasing overall vertical integration and memory density.

FIG. 3 illustrates a top-down view of an exemplary two-layer 3D memory array 300 with shared bit lines. In this implementation, both memory layers share the same set of vertical bit lines routed in metal layer M1. One layer of memory array 300 utilizes metal layers M1 (bit lines) and M2 (value lines), while the second layer uses M1 (bit lines) and M3 (value lines). This means that the vertical bit lines (e.g., 302, 304, 306, and 308) in M1 are reused across multiple value line layers (e.g., 312, 314, 316, 318, 352, 354, 356, and 358), reducing the total number of metal layers required.

Both memory arrays 100 and 300 have two memory layers. Memory array 100 in FIGS. 1 and 2 includes a total of four metal layers, with each memory layer containing two metal layers (one for bit lines and another for value lines). By contrast, memory array 300, shown in FIG. 3, employs a shared-bit-line configuration that reduces the required metal layers to three for the same two-layer structure. As a result, vertical memory density is significantly increased, enabling more data to be stored within the same physical footprint. This configuration also reduces routing complexity (particularly for bit lines) and supports greater scalability as more memory layers can be stacked within the same process constraints.

The shared-bit-line configuration in FIG. 3 provides a more compact and efficient use of available metal layers, enabling deeper stacking and increased storage capacity without increasing chip footprint or requiring more advanced and costly process nodes. However, as discussed below, this increase in density may come at the expense of operation speed. While the memory array 100 (depicted in FIGS. 1 and 2) supports a degree of parallel operation, for example, enabling memory rows in first layer 110 and second layer 150 to be accessed simultaneously, memory array 300 in FIG. 3 is limited in this regard and does not inherently support parallel access across its shared bit lines.

FIG. 4 illustrates a side view of the metal stack architecture used in the memory array 300 of FIG. 3. As shown, metal layer M1 is stacked with metal layers M2 and M3 in a manner that the value lines positioned in layers M2 and M3 can share the bit lines placed in layer M1. Each memory layer is still constructed using diode vias (e.g., PN junctions 402, 404) that support one-way electrical connections between value lines and bit lines.

### Sensing and Cell Capacity

Sensing refers to the process of detecting which memory cells are active (i.e., which value lines are connected to which bit lines) during a read operation. As to the operation of the ROM array in FIGS. 1-4, the value lines may be initialized using corresponding pre-charge buffers (not shown) to prepare for a reading operation. In some embodiments, the value lines may be pre-charged to different states or voltages, such as a high voltage, a low voltage, or a tri-state value (a state with no active drive), depending upon the characteristics of the memory array. Subsequent to the pre-charging, a specific combination of value line and bit line may be activated to have one or more values to be read.

The terms “active” and “inactive” refer to the electrical state of the value lines and bit lines during a sense (read) operation. The active or inactive polarity is flexible, that is, the system behavior is independent of whether “high” or “low” is chosen as “active.” However, for clarity, it is assumed that “active” would mean driving a value line to a high voltage, and “inactive” would mean driving a value line to a low voltage.

In some embodiments, the present system supports a single-value and single-bit sensing procedure (SVSB sense). At first, all bit lines are pre-charged to an inactive state (ground/low voltage). Since bit lines and value lines are selectively coupled with each other through diode vias (e.g., PN junctions) during the manufacturing and programming process, a bit line may be activated through the diode vias in response to activating a value line. When a specific value line is activated (e.g., driven high), a sensing circuit (not shown) monitors the bit lines to determine which diodes/connections conduct, revealing the stored data.

When a sense or read operation is initiated, all value lines are set to inactive except for the one value line being sensed. This sensed value line is driven with a specific voltage. Regardless of the sensed value line being driven to an active state (with a high voltage) or an inactive state (with a low voltage), all bit lines not connected to this sensed value line (i.e., without a diode via) will stay inactive.

If the sensed value line is driven active, all bit lines connected to this active value line through programmed diode vias will transition to active. However, if the sensed value line is driven inactive, the bit lines that were coupled to this value line during manufacturing will remain inactive. In other words, if a value line is driven inactive, all associated bit lines will remain inactive, regardless of diode connections. The one-way current flow feature of rectifying diodes prevents signal leakage back into other inactive value lines, preserving sensing accuracy.

In some embodiments, a sense amplifier (not shown) may detect the voltage change on the value line, for example, by comparing the voltage on the value line (changed or unchanged through the bit line connection) to the driven value. Depending upon the comparison result, the sense amplifier may determine a value of “0” or “1,” and output this detected bit as the stored ROM value. For example, if there is a voltage change, the output value may be “1.” Otherwise, the value is “0.”

Referring back to FIG. 1, if value line 112 is sensed and driven to an active state, bit lines 120 and 124 electrically coupled to value line 112 through PN junctions 136 and 138 will transition to active, while the other two non-connected bit lines 122 and 126 remain inactive. As a result, the stored values “1 0 1 0” are read.

During sensing, only one value line can be activated at a time, while all other value lines remain inactive. In FIG. 1, where row 0 of the first memory layer 110 contains four value lines, each value line is activated sequentially, not simultaneously. Therefore, when value line 112 is activated, value lines 114, 116, and 118 remain inactive. Additionally, since row 0 and row 1 of the first layer 110 share the same set of bit lines 120, 122, 124, and 126, value lines in different rows must also be accessed one at a time (i.e., sequentially not concurrently). For example, if value line 112 in row 0 is active and conducting a logic “1” through PN junction 136 on bit line 120, then value line 130 in row 1 cannot be driven simultaneously. If value line 130 were driven and attempted to read a logic ‘0’ through PN junction 140 connected to the same bit line 120, the conflicting drive levels would lead to incorrect or undefined behavior. This restriction preserves signal integrity and ensures unambiguous data retrieval during the sensing process.

When a value line is activated, the bit lines connected with the value line through diode vias will reflect the stored data. In the example of FIG. 1, four bits are allowed to be read per activation cycle from one memory layer of memory array 100. Thus, for one or more rows with multiple value lines, the memory is read serially, one value line at a time.

Memory array 100, as shown in FIGS. 1 and 2, however, provides parallelism across layers. In the standard stacking configuration in FIGS. 1 and 2, where each memory layer 110 and 150 has dedicated bit lines, it is possible to activate value lines from multiple layers simultaneously, enabling layer-level parallelism. For example, value line 112 from the first layer 110 and value line 154 from the second layer 150 can be active at the same time, doubling the effective read bandwidth.

The sensing mechanism within a memory layer is similar to that of memory array 300 shown in FIGS. 3 and 4. The memory is read serially, one value line at a time. For example, if value line 312 is active, other value lines in the same memory layer such as 314, 316, and 318 cannot be active at the same time. However, the shared-bit-line configuration in FIGS. 3 and 4, where bit lines are reused across layers to reduce metal usage and increase vertical packing density, imposes a constraint on parallelism across layers. Only one value line across all layers sharing the same bit lines can be activated at any given time. Activating multiple value lines would cause electrical contention, as two drivers could attempt to set different voltages on the same bit line. For example, value line 312 cannot be active simultaneously with value line 352 because they share bit lines 302 and 306.

### Multi-bit values

In the memory array described herein, the capacity of each storage cell is determined by the number of value lines, rather than scaling exponentially with the number of stored bits. In other words, each storage cell can store a number of bits equal to the number of value lines in the array, thereby avoiding the exponential growth in wiring complexity (e.g., 2ⁿ value lines for n bits) seen in some conventional designs. This efficiency is particularly advantageous for implementing multi-bit storage within a compact footprint.

Although only one bit per cell is retrieved per sensing cycle, the architecture described herein supports multi-bit storage per cell through successive activation cycles. For example, a 2-bit value can be read by activating the same value line in two cycles, where one bit of the multi-bit word is retrieved in each cycle. This bit-serial access scheme leverages the architecture’s high density, allowing compact multi-bit storage while maintaining the simplicity of one-way diode logic.

In some embodiments, multi-bit storage is achieved by extending SVSB. Multi-bit values are sensed by repeating the SVSB sense procedure multiple times in succession. A value line can be pre-charged and activated multiple times, and a multi-bit value can be obtained by shifting through successive “levels” or “positions” of information. During each sensing cycle, a different portion of a multi-bit value is retrieved. For example, by repeatedly performing the sense on value line 112 in FIG. 1, a bit line (e.g., 120 or 124) can be used to shift through (e.g., sequentially transmit) a multi-bit value (e.g., 2 bits). Two successive sensing cycles are used to retrieve the two bits. In the first sensing cycle, the least significant bit may be detected. In the second sensing cycle, the most significant bit may be detected. In this way, value line 112 carries 2-bit information across two sensing operations. In some embodiments, the SVSB may be controlled in a self-timed manner (e.g., delay lines) or by a clocked state machine, and then repeated to read multiple bits.

Overall, the architecture described herein enables a high-density, memory fabric that supports both storage and in-memory computation. The shared-bit-line configuration, as shown in FIGS. 3 and 4, results in higher storage density, as fewer metal layers are needed for the same number of storage layers. This is particularly beneficial when maximizing the number of parameters per chip, which is critical for applications such as AI model storage (e.g., billions to trillions of parameters). However, the shared configuration reduces read speed, as only one value line (and thus one set of bits) can be sensed at a time. In contrast, the standard stacking approach allows faster reads through parallel value line activation, but at the cost of using more metal layers and achieving lower overall density.

Moreover, the multi-bit storage approach described herein allows multi-bit value per value line, which helps avoid traditional exponential wiring (no 2ⁿ wires for n bits) and increases storage density without increasing physical complexity. The multi-bit storage supports scalable, in-memory computation with minimal routing burden, and enables compact high-capacity memory arrays that are important for AI/ML accelerators (as described below).

By leveraging dense stacking and eliminating transistors in the storage fabric, the architecture described herein can support orders of magnitude more parameters per chip. For example, what previously required multiple chips to store 20 billion parameters can now store 200 billion parameters per chip using stacked layers and bit-serial access. With multiple layers operating in parallel, system performance is preserved, while the cost and size of deploying large AI models are significantly reduced, potentially allowing models with trillions of parameters to fit within a single server.

### Compute in Memory

ML computations form the foundation of operations in a wide range of models and applications. In fully connected neural networks, matrices encode both the weights and activations associated with neurons across different layers, which capture the learned knowledge of the model. Matrix multiplications are critical because both training and inference processes require repeatedly multiplying these matrices to transform input features into outputs or predictions. However, the growth of neural networks in size and complexity brings significant challenges to computation, especially the number and scale of matrix operations. This has led to the development of specialized hardware and optimized memory architectures aimed at accelerating matrix multiplications efficiently and at scale.

The present approach is beneficial since it enables the integration of a more compact ROM structure across various use cases to support efficient data communication. The compute-in-memory functionality described herein can be leveraged to perform the matrix multiplications directly within the storage array. The present approach builds upon prior U.S. Patent Application No. 19/014,806, filed on Jan. 9, 2025. This application introduces a connectivity mesh configuration, where multiplier circuits, readable cells, a read circuit, and a selection circuit are interconnected for efficient, scalable communication. In particular, the readable cells may be configured similarly to a ROM cell. Each of the readable cells may be coupled to a bit line, and these bit lines can be used to pass precomputed values from a side table to outputs of a macro. By enabling multiple values to be sensed through a shared connection, the ROM implementation described herein aligns well with and supports the connectivity mesh-based scheme proposed in this patent application.

The key distinction in the present 3D variant is that sensing operations, specifically, single-value single-bit (SVSB) sense procedures, must be carried out serially across the value lines of a storage row, as opposed to the parallel sensing supported in earlier ‘806 implementations. Despite this difference, the underlying mechanism remains fundamentally the same, enabling efficient matrix-vector operations within the memory fabric and contributing to dense, high-throughput in-memory computation suitable for machine learning workloads.

### Flowchart

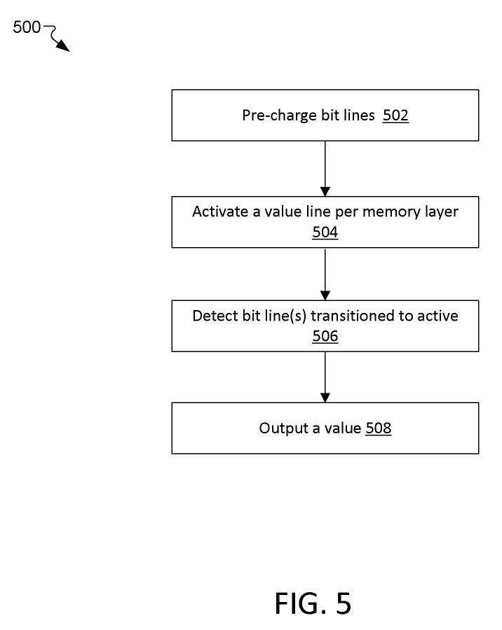

FIG. 5 illustrates a flow diagram 500 for a read operation of a memory array, according to some embodiments. In this flow diagram, steps are outlined to show how data from a set of bit lines associated with a specific value line may be read over multiple cycles. In some embodiments, flow diagram 500 may be applied to read the four bits associated with four bit lines and a value line of each memory layer 110, 150 of the memory array 100 shown in FIG. 1. In each cycle, one set of bit line’s worth of bits may be read from the first and second memory layers. In the example of FIG. 1, when a value line 112 is activated, this would result in four bits being read per cycle from the first layer 110. Concurrently, any one of the value lines of row 0 and row 1 of the second memory 150 may be activated, causing another four bits to be read per cycle from the second layer 150.

Flow diagram 500 starts with pre-charging all bit lines to an inactive state at step 502. This includes initializing the bit lines (e.g., 120, 122, 124, and 126 of the first layer 110 in FIG. 1, and 160, 162, 164, and 166 of the second layer 150 in FIG. 1) to prepare for the read operation. Next, at step 504, a value line may be sensed. This value line can be driven active (e.g., with a high voltage) or inactive (e.g., with a low voltage). All other value lines of the same memory layer stay inactive. Although only one value line in each memory layer can be activated at a time without causing conflicts, which limits the architecture to sequential sensing, another value line in another memory layer can be activated at the same time to support parallel operations across multiple layers.

If the value line is driven active, one or more bit lines may be activated, which determines the stored values/bits to be read. A bit line is monitored to determine if a connection exists. If a connection exists, current can flow through the diode via, causing a voltage drop or rise on a value line. If no connection exists, the current does not flow, and the value line voltage remains unchanged. At step 506, one or more bit lines are detected to be active.

Read process 500 continues to step 508 to output a value of reading the memory array based on the detecting the one or more bit lines transitioned to the active state with triggering sense amplifiers at step 506. A sense amplifier (not shown) may detect the voltage change on the value line, for example, by comparing the voltage on the value line (changed or unchanged through the bit line connection) to the pre-charge low value. Depending upon the comparison result, the sense amplifier may determine a value of “0” or “1,” and output this detected bit as the stored ROM value at step 508. For example, if there is a voltage change (drop or rise) compared to the pre-charged low value, the output value may be “1.” Otherwise, the value is “0.” Although only one bit per cell is retrieved per sensing cycle, the architecture described herein supports multi-bit storage per cell through successive activation cycles.

### Rectifying Vias

As discussed above in FIGS. 1-4, rectifying contacts or vias are employed to electrically couple specific bit lines and value lines positioned on different metal layers. The goal of building a rectifying via layer is to enable unidirectional current flow, functioning as a diode that allows high current flow in one direction (forward bias) while blocking current in the opposite direction (reverse bias). To ensure compatibility with 7-nanometer (nm) CMOS back-end-of-line (BEOL) processes, the rectifying via adheres to specific fabrication constraints. All materials and deposition processes should operate within a thermal budget of 150–300 Celsius (°C), consistent with BEOL requirements.

Additionally, the rectifying via should effectively fill high-aspect-ratio structures (typically 10–20 nm in diameter and 50–100 nm in height) with good conformality. The via structure should also be compatible with standard BEOL metals such as copper (Cu), tungsten (W), cobalt (Co), and interlayer dielectrics such as SiCOH. Importantly, the fabrication process should be as simple as possible while ensuring robust, reliable performance over time.

To create a rectifying via, a structure or material that introduces a potential barrier or enables asymmetric conduction, such as a Schottky junction, PN junction, or tunneling barrier, is required. Described below are three feasible approaches, along with compatible materials and deposition techniques optimized for the 7nm process.

### 1. Schottky Barrier Via (Metal-Semiconductor Junction)

A Schottky barrier via achieves rectification by leveraging the interface between a metal and a semiconductor to create a unidirectional current path. The semiconductor can be doped silicon, polysilicon, or a 2D material, and the metal is chosen to form a Schottky contact with an appropriate barrier height.

In some embodiments, the semiconductor layer can be doped silicon or amorphous silicon (a-Si). Both polysilicon and a-Si can be conformally deposited at a temperature range of 150–300 °C using techniques such as plasma-enhanced atomic layer deposition (PEALD) or plasma-enhanced chemical vapor deposition (PECVD), making them compatible with the thermal limits of 7nm CMOS BEOL processing. Additionally, heavy doping (e.g., n-type with phosphorus at concentrations ~10²⁰ cm⁻³) can be used to reduce resistivity and fine-tune the Schottky barrier height.

In fabricating a Schottky barrier via, the deposition of the semiconductor layer is important. Polysilicon can be conformally deposited using PEALD at temperatures ranging from 150 to 250°C. Alternatively, a-Si may be deposited using PECVD within a slightly higher temperature window of 200 to 300°C. To achieve the desired electronic properties, both materials are heavily doped in-situ during deposition, typically using phosphine (PH₃) or diborane (B₂H₆). This ensures a high concentration of dopants is incorporated into the silicon matrix, which lowers resistivity and adjusts the Schottky barrier height.

In some embodiments, the Schottky contact is established using metals such as titanium (Ti), nickel (Ni), or cobalt (Co), which is paired with a standard via metal such as tungsten (W) or Cu on the other side. Ti and Ni are chosen because they form rectifying junctions with n-type silicon, exhibiting barrier heights in approximately 0.5 to 0.6 eV. Co is particularly advantageous as it is already integrated into existing 7nm via processes and can be engineered for effective Schottky rectification. These metals Ti, Ni, and Co are typically deposited using physical vapor deposition (PVD) or atomic layer deposition (ALD) at relatively low temperatures 100–200°C, preserving compatibility with BEOL thermal budgets.

For the via fill, tungsten (W) or Cu is employed as the conductive metal to complete an electrical path. W is generally deposited through chemical vapor deposition (CVD), while Cu is commonly deposited through electroplating.

A complete via structure between metal layers (e.g., M2 and M3) includes: M2(Cu) Schottky metal (Ti/Ni) doped polysilicon ohmic metal (W/Co) M3 (Cu). That is, the layered stack starts with the M2 copper layer, followed by the Schottky metal (Ti or Ni), then the doped polysilicon, and next an ohmic metal contact such as W or Co, before terminating at the M3 copper layer. A thin Schottky junction is thus formed between the Schottky metal (Ti/Ni) and the doped polysilicon layer, providing rectifying behavior. Meanwhile, the opposite end of the silicon makes an ohmic contact with tungsten (W) or Co, ensuring a low-resistance electrical connection to the subsequent metal layer. This configuration not only supports unidirectional current flow but also aligns with the thermal and material requirements of advanced semiconductor nodes.

The fabrication process for a Schottky barrier via is described below. The process may begin with etching high-aspect-ratio vias into the interlayer dielectric (ILD), such as SiCOH, to electrically connect metal layers M2 and M3. Once the via openings are formed, a thin barrier or adhesion layer, typically titanium nitride (TiN), is deposited using ALD at temperatures between 150°C and 200°C. This layer, generally around 10 to 20 angstroms (Å) thick, prevents metal diffusion into the surrounding dielectric and ensures good adhesion of subsequent layers.

Next, the Schottky contact metal, such as titanium (Ti) of 5-10 nm, is deposited either via ALD or PVD, at temperatures in the range of 100°C to 200°C. This is followed by the deposition of the semiconductor layer, often doped polysilicon, using PEALD at 150°C to 250°C. During this step, PH₃ gas is introduced in situ to heavily dope the polysilicon n-type, reducing its resistivity and tuning the Schottky barrier height. The thickness of the polysilicon layer typically ranges from 20 to 50 nms.

After forming the Schottky junction, the via is completed by depositing an ohmic metal (e.g., tungsten (W)) using CVD at 200°C to 300°C. This metal provides a low-resistance contact to the M3 layer. Once the via is filled, chemical-mechanical polishing (CMP) is used to planarize the surface, preparing it for the deposition of the M3 copper layer.

This entire process is designed to comply with the strict thermal constraints of the 7nm CMOS BEOL process, with all deposition steps falling within the 150°C to 300°C window. The materials used, such as polysilicon, Ti, and Ni, are mature and well-characterized in CMOS manufacturing, which aids integration and reliability. Additionally, the rectification of the via can be tuned, for example, the barrier height can be adjusted based on the doping concentration level or the selection of Schottky metals (e.g., Ni yields a higher barrier, while Ti yields a lower barrier.

Despite its advantages, this approach presents some challenges. Polysilicon has a relatively high resistivity (~10⁻³ Ω·cm), which contributes to higher overall via resistance when compared to pure tungsten (W) (~5.6 µΩ·cm). As to interface control, the metal-semiconductor interface should be clean to prevent Fermi-level pinning, which may require ultra-high vacuum conditions during deposition. Moreover, scaling down vias presents a challenge, particularly when filling high-aspect-ratio structures with a multilayer stack including metal, polysilicon, and another metal. Achieving uniform and conformal deposition throughout such narrow and deep features requires ALD, crucial to maintain layer integrity and device performance at these dimensions.

In terms of performance, the Schottky barrier via exhibits strong rectifying behavior, with rectification ratios (forward current to reverse current) ranging from 10³ to 10⁵ depending on the exact doping and barrier characteristics. The forward voltage drop typically falls within 0.3 to 0.6 volts, which is acceptable for many integrated applications where moderate via resistance and voltage drop are permissible.

### 2. PN Junction Via (Doped Polysilicon)

A PN junction via incorporates a vertically stacked diode structure within a via by using heavily doped p-type and n-type polysilicon layers. This embedded diode enables strong rectification, conducting current efficiently in one direction (forward bias) while suppressing it in the opposite direction (reverse bias).

The core materials of a PN junction include p-type polysilicon, n-type polysilicon, and ohmic contacts. P-type polysilicon can be doped with boron to a concentration around 10²⁰ cm⁻³, and n-type polysilicon can be doped with phosphorus at a similar level. Polysilicon can be deposited and doped in situ at 150-300°C via PEALD or PECVD, forming a sharp PN junction. Also, the high doping concentrations can reduce the resistivity of the polysilicon and shrink the depletion region at the p-n interface, thereby enhancing diode performance.

Both types of doped polysilicon can be deposited conformally at low temperatures compatible with advanced CMOS BEOL integration. PEALD is the preferred method due to its superior step coverage and control, operating within the 150–250°C range using silane (SiH₄) as the silicon precursor and either B₂H₆ for p-type doping or PH₃ for n-type doping. PECVD can be alternatively used in the 200–300°C range, though it typically offers lower conformality.

To ensure robust electrical connectivity to the metal layers above and below the via, ohmic contacts are formed at both ends of the p-n stack. Materials such as TiN or tungsten (W) are suitable choices, with TiN deposited via ALD at 150–200°C and W deposited via CVD at 200–300°C.

The resulting structure can be represented as M2(Cu) TiN (ohmic) n-type polysilicon p-type polysilicon TiN(ohmic) M3(Cu). This is a vertical stack where the current flows from M2 (typically copper), through a TiN ohmic contact, into the n-type polysilicon, across the PN junction into the p-type region, and finally through another TiN ohmic contact into M3 (also copper). This configuration ensures effective diode action within the via, delivering rectification while remaining fully compatible with standard BEOL metallization processes. The embedded PN junction governs the directional current flow, while the ohmic contacts at both ends ensure low-resistance electrical connections to the adjacent metal layers (M2 and M3).

The fabrication process for a PN junction rectifying via begins with etching high-aspect-ratio vias in the ILD. Once the vias are defined, a thin TiN barrier layer, approximately 10 Å thick, is deposited using ALD at temperatures between 150°C and 200°C. This layer serves to prevent metal diffusion and improve adhesion.

Next, an n-type polysilicon layer is deposited via PEALD at 150°C to 250°C, with in-situ doping using PH₃ to achieve high phosphorus concentrations and reduce resistivity. A p-type polysilicon layer is also deposited using a similar PEALD process, with B₂H₆ introduced during deposition to ensure high boron doping. Each layer is typically 20 to 30 nm, and precise control of the doping interface is important to provide a sharp, high-performance junction.

After forming the PN junction, the via is filled with a conductive material such as tungsten (W) or additional TiN to create the top ohmic contact. This fill step maintains good step coverage and low resistivity. CMP is then used to planarize the surface and prepare for the subsequent metal layer (M3) deposition.

A PN junction offers strong rectification, with rectification ratios on the order of 10⁶ to 10⁸ and a well-defined turn-on voltage around 0.7 V. The fabrication process of PN junctions is thermally compatible with BEOL constraints, staying within a 150°C–250°C thermal budget. Additionally, PN junctions in polysilicon are highly compatible with standard CMOS processes, leveraging well-established doping and deposition technologies from transistor and memory applications. However, polysilicon’s resistivity may limit via conductivity, which can contribute to increased RC delays in high-speed circuits. The sequential deposition of doped layers within narrow vias demands excellent conformality and precise thickness control, meaning ALD is critical. Moreover, maintaining a sharp doping gradient at the p-n interface to avoid recombination losses in thin layers is also challenging.

Overall, PN junction vias exhibit a rectification ratio in the range of 10⁶ to 10⁸, making it highly effective for high-asymmetry applications (e.g., applications that demand strong directional current control or signal isolation). A forward voltage drop across the PN junction is approximately 0.7 volts, which is somewhat higher than that of Schottky diodes. However, this level is still within an acceptable range for many digital circuit applications, particularly those where leakage suppression and signal integrity are more important than minimal voltage drop.

Due to the relatively high resistivity of heavily doped polysilicon compared to metals, the PN junction via is better suited for low-speed, high-rectification use cases. These include situations where switching speed is not the primary concern, but where directional current flow and isolation between layers are critical—such as in 3D integration, memory arrays, or signal routing that requires embedded diode functionality.

### 3. 2D Material-Based Tunneling via

2D materials such as molybdenum disulfide (MoS₂) or graphene can form tunneling diodes or Schottky-like junctions with metals under the constrained geometries of 7nm vias, while offering rectification in ultra-thin layers and maintaining thermal compatibility with BEOL processing.

MoS₂, a layered 2D semiconductor, can form rectifying junctions when interfaced with metals, either through a Schottky barrier or via quantum tunneling. The rectification characteristics of MoS₂ can be tuned by controlling its thickness or selecting metals with appropriate work functions. MoS₂ films can be deposited using ALD with MoCl₅ and H₂S precursors at 150–250°C or through CVD at 200–300°C, compatible with BEOL temperatures. These methods allow for the growth of highly uniform films with monolayer to few-layer thicknesses (typically 1–3 layers of 2–5 nm), enabling precise control over electronic behavior.

Graphene, while metallic or semi-metallic depending on structure and doping, can also be used to form tunneling barriers or Schottky contacts with metals. Graphene is typically grown by CVD at 200–300°C on a catalytic metal surface (e.g., Cu), followed by a transfer process, though direct growth methods compatible with ALD-like techniques are also emerging. Graphene’s exceptional electron mobility and atomic thinness make it a potential candidate for fast-switching, low-leakage applications.

For metal contacts within a 2D-material-based rectifying via, nickel (Ni) or titanium (Ti) are good choices for forming Schottky or tunneling junctions with the MoS₂ or graphene layer. Ni and Ti offer suitable work functions that, when interfaced with MoS₂ or graphene, create the desired potential barrier for rectification. ALD or PVD can be used for the deposition of these metals (Ni, Ti) at temperatures between 100°C and 200°C, ensuring compatibility with BEOL processing constraints. The remainder of the via is filled with tungsten (W) or Co, which are standard fill metals in advanced CMOS nodes. For example, W can be deposited using CVD at temperatures between 200°C to 300°C, allowing reliable filling of high-aspect-ratio structures while maintaining thermal constraints.

The complete stack structure can be represented as M2(Cu) Ni (contact) MoS₂ (1-3 monolayers, 2-5nm) W (via fill) M3(Cu). In this typical structure, a rectifying via may be built as follows: a bottom metal layer (M2) of Cu interfaces with a thin contact metal such as Ni or Ti. This metal forms a junction with a thin MoS₂ layer (1–3 monolayers, approximately 2–5 nm thick), deposited conformally within the via. The MoS₂ acts as a tunneling or Schottky barrier, depending on the choice of metal and film thickness. The remaining volume of the via is filled with tungsten (W) or Co using standard CVD techniques to complete the electrical connection to the top metal layer (M3). The result is a highly compact, thermally compatible rectifying structure embedded directly within the interconnect stack, suitable for applications requiring ultra-thin diode functionality or signal directionality in densely packed circuits.

The fabrication process for a MoS₂-based rectifying via begins with etching vias through the ILD (e.g., metal layers M2 and M3). A thin TiN barrier, approximately 10 Å thick, is deposited via ALD at 150–20°C to prevent metal diffusion and to promote adhesion. Following this, a Ni layer roughly 5 nm thick is deposited using ALD at 100–200°C to serve as the Schottky contact. This contact metal plays an important role in establishing the rectifying behavior when paired with the MoS₂ layer.

Next, a monolayer or few-monolayer MoS₂ film (e.g., 1–3 monolayers) is deposited using ALD at 150–250°C. This ultra-thin semiconductor layer forms the core rectifying element in the via, creating a Schottky or tunneling barrier at the Ni–MoS₂ interface. The remaining volume of the via is filled with tungsten (W) and deposited via CVD at 200–300 °C, ensuring good electrical conductivity and compatibility with BEOL metallization. Finally, the surface is planarized and the M3 metal layer is deposited to complete the stack.

A 2D material-based tunneling via offers several advantages. The atomic thinness of MoS₂ (approximately 0.7 nm per monolayer) makes it ideally suited for high-aspect-ratio, scaled vias in advanced nodes. The fabrication process sequence fits within the 150–300°C thermal budget. Additionally, rectification performance can be finely tuned by adjusting MoS₂ thickness or the work function of the contact metal, providing flexibility for design optimization. However, the integration of 2D materials in 7nm BEOL processes is still experimental, with issues related to uniformity, defect control, etc. If CVD methods are used to grow MoS₂, subsequent transfer steps may introduce additional defects and variability. Furthermore, while tunneling barriers based on MoS₂ offer better rectification than traditional polysilicon-based vias, they still exhibit higher resistance compared to conventional metallic vias.

From a performance perspective, MoS₂-based vias can achieve rectification ratios in the range of 10³ to 10⁵, depending on the quality of the MoS₂ layer and the sharpness of the interface. The forward voltage drop is relatively low, around 0.3–0.5 V (lower than PN junctions), which is advantageous for low-power applications. These vias are best suited for cutting-edge, high-density circuits where novel electrical properties are prioritized.

### Proposed Via Solutions

Based on the comprehensive evaluation of three types of via approaches (as discussed above) on various aspects such as process feasibility, electrical performance, and compatibility with 7 nm BEOL technology, a Schottky barrier via employing doped polysilicon with a Ti or Ni contact emerges as the most practical and effective solution (hereafter referred to as “recommended via”). This approach strikes an optimal balance between manufacturability and functionality while aligning with the stringent thermal and integration constraints of advanced FinFET nodes.

One of the primary advantages of the recommended via is its adherence to the 150–250°C thermal budget. Both PEALD of doped polysilicon and ALD of Ti or Ni can be executed within this range. This ensures compatibility with temperature-sensitive low-k dielectrics and prevents degradation of device performance in tightly packed 7 nm structures.

The material set, polysilicon and Ti/Ni, is mature and has a well-established integration process, reducing the adoption barriers especially when compared to the 2D material-based (e.g., MoS₂ or graphene) vias. Moreover, the rectification performance offered by the recommended via is moderate but adequate for many specialized applications such as selective signal routing or power management, with typical rectification ratios ranging from 10³ to 10⁵.

The recommended vias also offer simpler process integration compared to PN junction vias requiring more layers and 2D material-based vias associated with experimental challenges. The recommended Schottky vias require fewer deposition steps while still delivering effective rectification, reducing overall process complexity and cost.

In some embodiments, the preferred stack of the recommended via includes M2 (Cu) TiN (barrier) Ti (5 nm, Schottky contact) n-type polysilicon (20–30 nm, deposited by PEALD and doped with phosphorus) tungsten (W) (via fill) M3 (Cu). Some important deposition steps include ALD of TiN at 150–200°C, ALD of Ti at 100–200°C, PEALD of doped polysilicon at 150–250°C, and CVD of W at 200–300°C.

To optimize electrical performance, heavy n-type doping (~10²⁰ cm⁻³) should be employed to reduce the resistivity of polysilicon and lower the effective barrier height at the metal-semiconductor interface. It is also important to maintain a clean, oxide-free interface between Ti and the doped polysilicon, which may be achieved through in-situ deposition under ultra-high vacuum conditions to minimize defect formation and Fermi-level pinning. Moreover, circuit-level simulations of via resistance and rectification should be performed to validate the design against performance targets.

Alternatively, a PN junction via can be chosen when high rectification performance is important, particularly in applications requiring significant asymmetry in current flow. With rectification ratios in the range of 10⁶ to 10⁸, this approach delivers strong diode behavior and sharp turn-on characteristics. However, this performance may be associated with increased electrical resistance (e.g., due to the semiconducting nature of polysilicon) and greater process complexity (e.g., due to the need for sequential deposition of precisely doped p- and n-type layers). As a result, PN junction vias are well-suited for low-speed, high-rectification applications where power efficiency and current directionality are more critical than speed or minimal RC delay.

The MoS₂ tunneling via, by contrast, is most suitable for cutting-edge or ultra-scaled technologies, such as 5 nm nodes or smaller, where minimal physical dimensions and novel material properties offer compelling advantages. The ultra-thin nature of 2D materials like MoS₂ allows for diodes only a few nanometers thick, providing a path toward extreme scaling. However, this approach still requires process development and validation before deployment in mainstream semiconductor manufacturing.

When implementing any rectifying via structure, several additional considerations must be addressed to ensure functionality and manufacturability. Unlike conventional tungsten (W) or copper (Cu)-filled vias, rectifying vias incorporate semiconducting or tunneling layers, which inherently increase electrical resistance and thus may introduce signal delay and degrade circuit performance. This may be addressed based on the adjustment of circuit parameters, for example, increasing driver strength or tolerating higher RC delays, to maintain acceptable signal integrity and timing.

Reliability is another important factor when integrating new materials or junction types into the BEOL stack. Potential failure mechanisms, such as electromigration, thermal instability, or interfacial degradation, may compromise device longevity and yield. A thorough assessment should be implemented at early-stage reliability testing to validate the robustness of the rectifying via under typical operating environments.

Simulations can be conducted to support design optimization, help identify process sensitivities, and reduce the likelihood of unexpected issues during silicon validation. For example, technology computer-aided design (TCAD) tools (e.g., Synopsys Sentaurus) can be used to simulate the current–voltage (I–V) characteristics of the proposed rectifying structures within a 7 nm via geometry before fabrication. Moreover, it is important to consult with the foundry (e.g., TSMC^{®}, Intel^{®}) to ensure the proposed materials and processes align with the 7nm design rules and toolsets.

### Additional Considerations

While the specification has been described in detail with respect to specific embodiments of the invention, it will be appreciated that those skilled in the art, upon attaining an understanding of the foregoing, may readily conceive of alterations to, variations of, and equivalents to these embodiments. Any of the method steps discussed above can be conducted by a processor operating with a computer-readable non-transitory medium storing instructions for those method steps. The computer-readable medium may be memory within a personal user device or a network accessible memory. Although examples in the disclosure were generally directed to machine intelligence applications, the same approaches could be utilized to other computationally intensive applications including cryptographic computations, ray tracing computations, and others. As another example, although examples in the disclosure were generally directed to computations in which multiplication operations must be conducted on a data structure with a number of parameters that is much larger than the potential values of those parameters, the same approaches can be used for different operations in place of the multiplication such as division, subtraction, addition, roots, logarithms, exponents, factorials, and any other mathematical or logical operation. These and other modifications and variations to the present invention may be practiced by those skilled in the art, without departing from the scope of the present invention, which is more particularly set forth in the appended claims.

### Terminology

The phraseology and terminology used herein is for the purpose of description and should not be regarded as limiting.

The term “approximately”, the phrase “approximately equal to”, and other similar phrases, as used in the specification and the claims (e.g., “X has a value of approximately Y” or “X is approximately equal to Y”), should be understood to mean that one value (X) is within a predetermined range of another value (Y). The predetermined range may be plus or minus 20%, 10%, 5%, 3%, 1%, 0.1%, or less than 0.1%, unless otherwise indicated.

The indefinite articles “a” and “an,” as used in the specification and in the claims, unless clearly indicated to the contrary, should be understood to mean “at least one.” The phrase “and/or,” as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The use of “including,” “comprising,” “having,” “containing,” “involving,” and variations thereof, is meant to encompass the items listed thereafter and additional items.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Each numerical value presented herein, for example, in a table, a chart, or a graph, is contemplated to represent a minimum value or a maximum value in a range for a corresponding parameter. Accordingly, when added to the claims, the numerical value provides express support for claiming the range, which may lie above or below the numerical value, in accordance with the teachings herein. Absent inclusion in the claims, each numerical value presented herein is not to be considered limiting in any regard.

The terms and expressions employed herein are used as terms and expressions of description and not of limitation, and there is no intention, in the use of such terms and expressions, of excluding any equivalents of the features shown and described or portions thereof. In addition, having described certain embodiments of the invention, it will be apparent to those of ordinary skill in the art that other embodiments incorporating the concepts disclosed herein may be used without departing from the spirit and scope of the invention. The features and functions of the various embodiments may be arranged in various combinations and permutations, and all are considered to be within the scope of the disclosed invention. Accordingly, the described embodiments are to be considered in all respects as only illustrative and not restrictive. Furthermore, the configurations, materials, and dimensions disclosed herein are intended as illustrative and in no way limiting. Similarly, although physical explanations have been provided for explanatory purposes, there is no intent to be bound by any particular theory or mechanism, or to limit the claims in accordance therewith.

What is claimed is:

1. A multi-layer read-only memory array comprising:
a plurality of vertically stacked memory layers, each memory layer comprising a plurality of bit lines positioned on a first set of metal layers and a plurality of value lines positioned on a second set of metal layers,
wherein the plurality of value lines and the plurality of bit lines are selectively connected by rectifying contacts configured to allow one-way current flow.

2. The memory array of claim 1, wherein the memory array allows metal-pitch density by removing transistors from and including only the metal layers in associated storage regions.

3. The memory array of claim 1, wherein the rectifying contacts comprise Schottky barrier vias, PN junction vias, or two-dimensional based tunneling vias.

4. The memory array of claim 1, wherein the memory array is mask-programmable.

5. The memory array of claim 1, wherein each memory cell of the memory array stores a multi-bit value corresponding to a number of the value lines, and wherein the multi-bit value is read by sequentially performing single-value, single-bit (SVSB) sense operations across the associated value lines.

6. The memory array of claim 5, wherein values stored in the memory array represent neural network parameters, and the values are used to perform vector-by-matrix multiplications.

7. The memory array of claim 1, wherein memory density is improved by eliminating word line and access transistor routing, and wherein in-memory compute logic is located outside the storage fabric of the memory array.

8. A method of manufacturing a three-dimensional (3D) read-only memory array comprising:
etching a pair of contact holes at a specific position of a first metal layer and a second metal layer;
forming rectifying vias through each pair of contact holes by depositing one or more doped semiconductor layers or metal-semiconductor junctions; and
selectively connecting value lines to bit lines based on placement of the rectifying vias.

9. The method of claim 8, wherein the rectifying vias are selectively formed between the value lines and bit lines such that activation of one of the value lines causes only the bit lines connected through the rectifying vias to transition to an active state during operation of the 3D memory array.

10. The method of claim 8, further comprising:
repeating the etching, forming rectifying vias, and selectively connecting steps on additional metal layers to create the 3D memory array.

11. The method of claim 10, wherein the 3D memory array comprises a plurality of metal layers stacked vertically.

12. The method of claim 8, wherein the rectifying vias comprise Schottky barrier vias, PN junction vias, or two-dimensional based tunneling vias.

13. A method for reading data from a memory array comprising a plurality of bit lines and a plurality of value lines, the method comprising:
pre-charging the plurality of bit lines to an inactive state;
sensing and driving a specific value line of the plurality of value lines while setting remaining value lines to an inactive state;
detecting one or more bit lines of the plurality of bit lines transitioned to an active state, wherein the one or more bit lines are electrically coupled to the sensed value line by one or more rectifying diode vias; and
outputting a value as a result for reading the memory array based on the detecting the one or more bit lines transitioned to the active state.

14. The method of claim 13, wherein active states of the one or more bit lines represent stored bits coupled to the sensed value line.

15. The method of claim 13, wherein single-value and single-bit (SVSB) sense operations are performed serially across value lines in a given memory row.

16. The method of claim 15, further comprising repeating the SVSB sense operations in succession to read multiple bits from each memory cell of the memory array.

17. The method of claim 13, wherein the memory array comprises a plurality of vertically-stacked memory layers.

18. The method of claim 17, wherein sensing and driving the specific value line is performed in parallel across the memory layers of the memory array.

19. The method of claim 13, wherein values stored in the memory array represent neural network parameters, and the values are used to perform vector-by-matrix multiplications.

20. The method of claim 13, wherein the memory array is mask-programmable.
